(19) United States
(12) Patent Application Publication
(10) Pub. No.: US 2026/0052792 A1
(43) Pub. Date: Feb. 19, 2026

(54) LIGHT DETECTION DEVICE

(71) Applicant: SONY SEMICONDUCTOR SOLUTIONS CORPORATION, Kanagawa (JP)

(72) Inventors: Sawako TANAKA, Kanagawa (JP); Yoshiki EBIKO, Kanagawa (JP)

(73) Assignee: SONY SEMICONDUCTOR SOLUTIONS CORPORATION, Kanagawa (JP)

(21) Appl. No.: 19/101,822

(22) PCT Filed: Aug. 10, 2023
(86) PCT No.: PCT/JP2023/029289

§ 371 Date: Feb. 6, 2025

(30) Foreign Application Priority Data
Aug. 17, 2022 (JP) 2022-130258

(51) Int. Cl. H10F 39/00; H01L 23/522

(52) U.S. Cl. CPC H10F 39/809; H01L 23/5223; H10F 39/811

(57) ABSTRACT

Provided is a low-cost light detection device with large signal detection capacity. The light detection device includes a first semiconductor substrate including a first semiconductor layer and a second semiconductor layer stacked on top of each other. The first semiconductor layer includes a photoelectric conversion region and a floating diffusion region that accumulates charges resulting from photoelectric conversion in the photoelectric conversion region, and the second semiconductor layer includes a capacitor that accumulates the charges resulting from photoelectric conversion in the photoelectric conversion region.

### TECHNICAL FIELD

The present disclosure relates to a light detection device.

### BACKGROUND ART

For a complementary metal oxide semiconductor (CMOS) solid-state imaging device, in order to enhance sensitivity, a structure capable of accumulating more signal charges generated in a photoelectron converter (light receiver) is desirable. From such a background, a structure where a capacitor that accumulates signal charges is provided in addition to a floating diffusion capacitance (FD) has been proposed (see Patent Document 1).

The solid-state imaging device disclosed in Patent Document 1 includes a first substrate including a photoelectric conversion element, and a second substrate that is located on a side opposite to a light incident surface of the photoelectric conversion element of the first substrate and includes a capacitor that accumulates charges transferred from the photoelectric conversion element.

### CITATION LIST

### Patent Document

Patent Document 1: Japanese Patent Application Laid-Open No. 2020-47734

### SUMMARY OF THE INVENTION

### Problems to be Solved by the Invention

According to Patent Document 1, it is possible to increase the signal detection capacity and expand the dynamic range by accumulating the charges transferred from the photoelectric conversion element in the capacitor provided in the second substrate.

As disclosed in Patent Document 1, it is, however, necessary to provide the second substrate including the capacitor separately from the first substrate including the photoelectric conversion element, which makes the manufacturing process complex and makes it difficult to reduce the manufacturing cost.

It is therefore an object of the present disclosure to provide a light detection device capable of enhancing sensitivity without making a structure complex.

### Solutions to Problems

To solve the above problems, the present disclosure provides a light detection device including a first semiconductor substrate including a first semiconductor layer and a second semiconductor layer stacked on top of each other, in which
the first semiconductor layer includes a photoelectric conversion region and a floating diffusion region that accumulates charges resulting from photoelectric conversion in the photoelectric conversion region, and
the second semiconductor layer includes a capacitor that accumulates the charges resulting from photoelectric conversion in the photoelectric conversion region.

The second semiconductor layer may include a gate electrode of a transfer transistor that transfers the charges resulting from photoelectric conversion in the photoelectric conversion region to the floating diffusion region,
the capacitor may include a first electrode, a second electrode arranged to face the first electrode, and a dielectric arranged between the first electrode and the second electrode, and the first electrode and the second electrode may be arranged at a layer height that is between a same layer height as the gate electrode and a same layer height as a wiring layer connected to the gate electrode through a contact.

The first electrode may be arranged at the same layer height as the gate electrode, and
the second electrode may be arranged at the same layer height as the wiring layer.

The first electrode may be arranged at the same layer height as the gate electrode, and the second electrode may be arranged between the gate electrode and the wiring layer.

The first electrode may be arranged between the gate electrode and the wiring layer, and
the second electrode may be arranged at the same layer height as the wiring layer.

The first electrode and the second electrode may be arranged between the wiring layer and the gate electrode.

The first electrode and the second electrode may have uneven sections that mesh with each other with a gap provided between opposing surfaces of the first electrode and the second electrode.

The dielectric may include an insulating material different from an etching stopper layer arranged between the wiring layer and the gate electrode.

The dielectric may include the same insulating material as an etching stopper layer arranged between the wiring layer and the gate electrode.

The gate electrode, the wiring layer, the first electrode, and the second electrode may include polysilicon.

The first electrode may be set to a predetermined negative potential.

One electrode of the first electrode or the second electrode may include a columnar member extending in a depth direction of the second semiconductor layer, and
another electrode of the first electrode or the second electrode may include a tubular member covering at least a side surface of the one electrode with the dielectric interposed therebetween.

The first electrode and the second electrode may extend in a depth direction of the second semiconductor layer.

Opposing surfaces of the first electrode and the second electrode may be arranged along a depth direction of the second semiconductor layer.

The two electrodes of the capacitor may be arranged approximately in parallel in a region of a pixel in plan view.

The first semiconductor layer may include
a plurality of pixels each having the photoelectric conversion region, and
a pixel boundary region arranged between two pixels adjacent to each other of the plurality of pixels, and
the capacitor may be arranged in a region that coincides with each of the pixels in plan view.

The first semiconductor layer may include
a plurality of pixels each having the photoelectric conversion region, and
a pixel boundary region arranged between two pixels adjacent to each other of the plurality of pixels, and
the capacitor may be arranged in a region that coincides with the pixel boundary region in plan view.

The second semiconductor layer may include a switching transistor that switches whether or not to transfer the charges accumulated in the floating diffusion region to the capacitor.

A second semiconductor substrate that is arranged on a side opposite to a light incident surface of the first semiconductor substrate and processes a pixel signal corresponding to the charges resulting from photoelectric conversion in the photoelectric conversion region may be further provided.

Opposing surfaces of the first semiconductor substrate and the second semiconductor substrate may be bonded to each other by a contact between pads, a via, or a bump.

### BRIEF DESCRIPTION OF DRAWINGS

FIG. 1 is a block diagram illustrating an example of a schematic configuration of an embodiment of a solid-state imaging device to which the present technology is applied.

FIG. 2 is a circuit diagram illustrating an example of a schematic configuration of a unit pixel in an effective pixel region.

FIG. 3 is a cross-sectional view illustrating an example of a cross-sectional structure of the unit pixel.

FIG. 4 is a plan view illustrating an arrangement of capacitors in the pixels.

FIG. 5 is an enlarged cross-sectional view illustrating an example of a cross-sectional structure of a unit pixel according to a second embodiment.

FIG. 6 is a plan view illustrating an arrangement of capacitors in the pixels according to the second embodiment.

FIG. 7 is an enlarged cross-sectional view illustrating an example of a cross-sectional structure of a unit pixel according to a third embodiment.

FIG. 8 is an enlarged cross-sectional view illustrating an example of a cross-sectional structure of a unit pixel according to a fourth embodiment.

FIG. 9 is a cross-sectional view illustrating an example of a cross-sectional structure of a unit pixel according to a fifth embodiment.

FIG. 10 is an enlarged cross-sectional view illustrating an example of a cross-sectional structure of a unit pixel according to a sixth embodiment.

FIG. 11 is a plan view illustrating a shape and arrangement of capacitors in pixels according to a seventh embodiment.

FIG. 12 is an enlarged cross-sectional view illustrating an example of a cross-sectional structure of a unit pixel according to an eighth embodiment.

FIG. 13 is an enlarged cross-sectional view illustrating an example of a cross-sectional structure of a capacitor according to the eighth embodiment.

FIG. 14 is a plan view illustrating an arrangement of the capacitors in the pixels according to the eighth embodiment.

FIG. 15 is an enlarged cross-sectional view illustrating an example of a cross-sectional structure of a unit pixel according to a ninth embodiment.

FIG. 16 is a plan view illustrating an arrangement of capacitors in the pixels according to the ninth embodiment.

FIG. 17 is a plan view illustrating an arrangement of capacitors in pixels according to a tenth embodiment.

FIG. 18 is a block diagram illustrating an example of a schematic configuration of a vehicle control system.

FIG. 19 is an explanatory diagram illustrating an example of installation positions of an outside-vehicle information detecting section and an imaging section.

### MODE FOR CARRYING OUT THE INVENTION

Hereinafter, embodiments of a light detection device will be described with reference to the drawings. In the following, main components of the light detection device will be described, but the light detection device may have components and functions that are not illustrated or described. The following description is not intended to exclude components and functions that are not illustrated or described.

### FIRST EMBODIMENT

### Example of Schematic Configuration of Solid-State Imaging Device

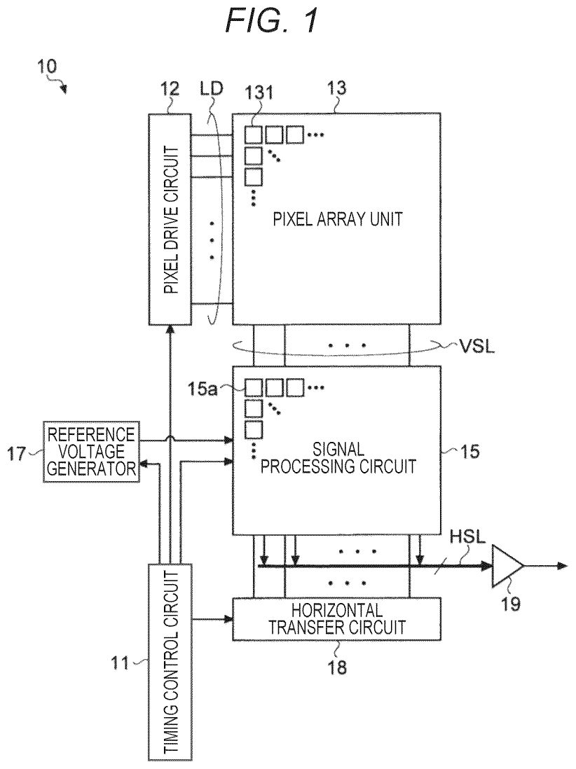

FIG. 1 is a block diagram illustrating an example of a schematic configuration of an embodiment of a solid-state imaging device to which the present technology is applied. A CMOS solid-state imaging device according to a first embodiment is an electronic device including a light detection device to which the present technology is applied. Note that, in the following description, the CMOS solid-state imaging device is referred to as CMOS image sensor or is simply referred to image sensor or solid-state imaging device. Note that the light detection device to which the present technology is applied may be a sensor other than an image sensor.

As illustrated in FIG. 1, an image sensor 10 according to the present embodiment includes a pixel array unit 13, a signal processing circuit 15, a reference voltage generator 17, and an output circuit 19.

Furthermore, the image sensor 10 in FIG. 1 includes a drive control unit configured to sequentially read an analog pixel signal from each unit pixel 131 and output digital image data, separately from the pixel array unit 13. The drive control unit includes, for example, a horizontal transfer circuit 18, a pixel drive circuit 12, a timing control circuit 11, and the like.

The pixel array unit 13 includes a plurality of the unit pixels 131 arranged in a two-dimensional matrix in row and column directions. In FIG. 1, for the sake of simplification of description, although some of the rows and columns in the pixel array unit 13 have been omitted, a plurality of the unit pixels 131 can be arranged in each row and each column, for example.

Each unit pixel 131 is connected to the pixel drive circuit 12 through a pixel drive line LD used for pixel selection and is further connected one-to-one to an AD conversion circuit 15a to be described later through a vertical signal line VSL. Note that, in the present description, the pixel drive line LD refers to all wirings extending from the pixel drive circuit 12 to each unit pixel 131. For example, the pixel drive line LD may include a control line through which various pulse signals (for example, a pixel reset pulse, a transfer pulse, a drain line control pulse, and the like) propagate to drive each unit pixel 131.

The signal processing circuit 15 includes an analog circuit such as the analog to digital (AD) conversion circuit 15a that converts the analog pixel signal read from each unit pixel 131 into the digital pixel signal, and a logic circuit that performs digital processing such as correlated double sampling (CDS) processing on the basis of the pixel signal resulting from the conversion into a digital value performed by the AD conversion circuit 15a. Note that, for example, the AD conversion circuit 15a may be provided on a one-to-one basis for each unit pixel 131, may be provided on a one-to-one basis for each pixel group including a plurality of the unit pixels 131, or may be provided on a one-to-one basis for each column of the pixel array unit 13. Note that FIG. 1 illustrates a configuration where a plurality of the AD conversion circuits 15a is arranged in a two-dimensional matrix in the row and column directions, but the present disclosure is not limited to such a configuration.

For example, each AD conversion circuit 15a performs AD conversion to separately convert a reset level that is a reference level of the pixel signal and a signal level corresponding to the amount of received light into digital data. Furthermore, each AD conversion circuit 15a further performs differential processing (corresponding to correlated double sampling (CDS) processing) to acquire a digital pixel signal representing a signal component corresponding to the amount of received light. During this CDS processing, processing to calculate a difference between the AD conversion result of the reset level and the AD conversion result of the signal level is performed. Note that the AD conversion circuit 15a may be, for example, a single-slope AD conversion circuit or a successive approximation register (SAR) AD conversion circuit.

The reference voltage generator 17 supplies, to the signal processing circuit 15, a reference voltage REF to convert the analog pixel signal read from each unit pixel 131 through the vertical signal line VSL into the digital pixel signal. For example, in a case where the AD conversion circuit 15a is of the single-slope type, the reference voltage generator 17 outputs the reference voltage REF having a sawtooth waveform (also referred to as ramp waveform) that steps up or down linearly or stepwise. On the other hand, in a case where the AD conversion circuit 15a is of the successive approximation register type, the reference voltage generator 17 outputs the reference voltage REF having a constant voltage value. In this case, each AD conversion circuit 15a generates a plurality of reference voltages to be used for successive approximation, for example, by dividing the reference voltage REF that is a constant voltage.

The timing control circuit 11 outputs an internal clock necessary for each unit to operate, a pulse signal that provides timing at which each unit starts operating, and the like. Furthermore, the timing control circuit 11 receives data representing a master clock, an operating mode, and the like from the outside, and outputs data including information regarding the image sensor 10.

For example, the timing control circuit 11 outputs, to the pixel drive circuit 12, a pulse signal that provides timing at which the pixel signal is read from each unit pixel 131. Furthermore, the timing control circuit 11 outputs, to the horizontal transfer circuit 18, a column address signal to cause the horizontal transfer circuit 18 to sequentially read pixel signals (digital voltage values) each representing the signal component resulting from the AD conversion performed by the AD conversion circuit 15a from the signal processing circuit 15 for each column.

Moreover, in the timing control circuit 11, a clock identical in frequency to the master clock input from the outside, a clock resulting from dividing the clock by two, or a low-speed clock resulting from further division, or the like is supplied as the internal clock to each unit in the image sensor 10 such as the horizontal transfer circuit 18, the pixel drive circuit 12, and the signal processing circuit 15. Hereinafter, clocks including the clock resulting from dividing by two and clocks having lower frequencies are collectively referred to as low-speed clock.

The pixel drive circuit 12 selects a row of the pixel array unit 13 and outputs a pulse necessary for driving the row to the pixel drive line LD. For example, a vertical decoder that determines a row to be read from among the rows arranged in the vertical direction (selects a row of the pixel array unit 13) and a vertical drive unit that supplies a pulse to the pixel drive line LD to drive the unit pixel 131 on the read address (in the row direction) determined by the vertical decoder are included. Note that the vertical decoder selects not only the row from which the pixel signal is read but also a row for electronic shutter or the like.

In accordance with the column address signal input from the timing control circuit 11, the horizontal transfer circuit 18 performs a shift operation (scanning) to read the digital pixel signal from each AD conversion circuit 15a of the read column specified by the column address signal to the horizontal signal line HSL.

The output circuit 19 outputs the digital pixel signal read by the horizontal transfer circuit 18 to the outside as image data.

Note that the signal processing circuit 15 may include, as necessary, another circuit such as an auto gain control (AGC) circuit having a signal amplification function.

Furthermore, the image sensor 10 may be provided with a clock converter that is an example of a high-speed clock generator and generates a pulse having a clock frequency higher than the input clock frequency. In this case, the timing control circuit 11 may generate the internal clock on the basis of the input clock (for example, the master clock) input from the outside or the high-speed clock generated by the clock converter.

### Example of Circuit Configuration of Unit Pixel

Next, an example of a circuit configuration of the unit pixels 131 arranged in a matrix in the pixel array unit 13 in FIG. 1 will be described.

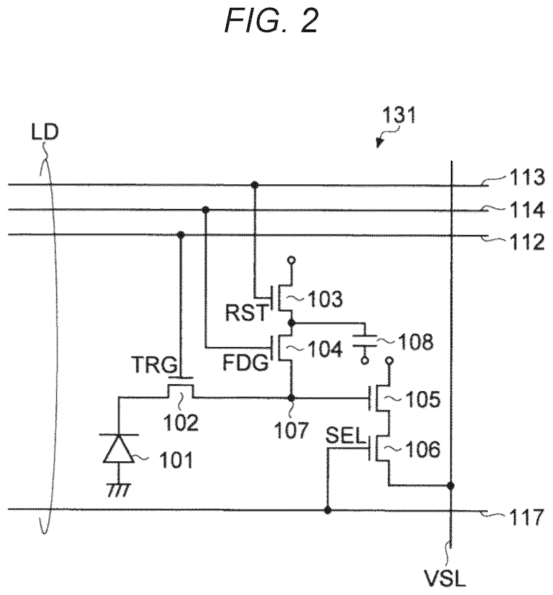

FIG. 2 is a circuit diagram illustrating an example of a schematic configuration of a unit pixel in an effective pixel region. As illustrated in FIG. 2, the unit pixel 131 includes a photodiode 101, a transfer transistor 102, a reset transistor 103, a switching transistor 104, an amplification transistor 105, a selection transistor 106, a node 107 as a first floating diffusion, a capacitor 108 as a second floating diffusion, a selection transistor drive line 117 as the pixel drive line LD having one end connected to the pixel drive circuit 12, a reset transistor drive line 113, a switching transistor drive line 114, a transfer transistor drive line 112, and the vertical signal line VSL having one end is connected to the signal processing circuit 15.

The photodiode 101 photoelectrically converts incident light. The transfer transistor 102 transfers charges generated in the photodiode 101. The node 107 and the capacitor 108 functioning as the first and second floating diffusions accumulate the charges transferred by the transfer transistor 102. The switching transistor 104 controls to cause the capacitor 108 to accumulate the charges. The switching transistor 104 therefore switches whether or not to transfer the charges accumulated in the node 107 to the capacitor 108.

The amplification transistor 105 causes a pixel signal representing a voltage corresponding to the charges accumulated in the node 107 or the node 107 and the capacitor 108 to appear on the vertical signal line VSL. The reset transistor 103 releases the charges accumulated in the node 107 or the node 107 and the capacitor 108. The selection transistor 106 selects a unit pixel 131 to be read.

The photodiode 101 has an anode grounded and has a cathode connected to a source of the transfer transistor 102. The transfer transistor 102 has a drain connected to a source of the switching transistor 104 and a gate of the amplification transistor 105, and the node 107, which is the connection point, serves as the first floating diffusion.

The reset transistor 103 and the switching transistor 104 are arranged in series with respect to the node 107. Note that the reset transistor 103 has a drain connected to a vertical reset input line (not illustrated).

The amplification transistor 105 has a source connected to a vertical current supply line (not illustrated). The amplification transistor 105 has a drain connected to a source of the selection transistor 106, and the selection transistor 106 has a drain connected to the vertical signal line VSL.

A gate of the transfer transistor 102, a gate of the reset transistor 103, a gate of the switching transistor 104, and a gate of the selection transistor 106 are connected to the pixel drive circuit 12 through the pixel drive line LD and receive a pulse as a drive signal.

The node 107 functioning as the first floating diffusion and the capacitor 108 functioning as the second floating diffusion each convert the accumulated charges into a voltage corresponding to the amount of the charges. Note that the first floating diffusion is, for example, a floating diffusion region and is a capacitance to ground between the node 107 and the ground. The first floating diffusion, however, is not limited to the above, and may be a capacitance intentionally added by connecting a capacitor or the like to the node 107.

Furthermore, the capacitor 108 functioning as the second floating diffusion converts the accumulated charges into a voltage corresponding to the amount of the charges.

### Example of Basic Function of Unit Pixel

Next, a basic function of the unit pixel 131 will be described. The reset transistor 103 operates when a switching signal FDG applied to the gate of the switching transistor 104 is always in a High state to enable or disable the discharge of the charges accumulated in the node 107 and the capacitor 108 in accordance with a reset signal RST supplied from the pixel drive circuit 12.

When the High-level reset signal RST is input to the gate of the reset transistor 103, the node 107 and the capacitor 108 are clamped to a voltage applied through the vertical reset input line. Accordingly, the charges accumulated in the node 107 and the capacitor 108 are discharged (reset).

Furthermore, when the Low-level reset signal RST is input to the gate of the reset transistor 103, the node 107 and the capacitor 108 are electrically disconnected from the vertical reset input line to become floating.

The switching transistor 104 operates when the reset signal RST is always in the High state to enable or disable the discharge of the charges accumulated in the node 107 in accordance with the switching signal FDG supplied from the pixel drive circuit 12.

When the High-level switching signal FDG is input to the gate of the switching transistor 104, the node 107 is clamped to the voltage applied through the vertical reset input line. Accordingly, the charges accumulated in the node 107 are discharged (reset).

Furthermore, when the Low-level switching signal FDG is input to the gate of the switching transistor 104, the node 107 is electrically disconnected from the vertical reset input line to become floating.

The photodiode 101 photoelectrically converts incident light to generates charges corresponding to the amount of light. The generated charges are accumulated on a cathode side of the photodiode 101. The transfer transistor 102 enables or disables the transfer of the charges from the photodiode 101 to the node 107 or the node 107 and the capacitor 108 in accordance with a transfer control signal TRG supplied from the pixel drive circuit 12.

For example, when the High-level transfer control signal TRG is input to the gate of the transfer transistor 102, the charges accumulated in the photodiode 101 are transferred to the node 107 or the node 107 and the capacitor 108. On the other hand, when the Low-level transfer control signal TRG is supplied to the gate of the transfer transistor 102, the transfer of the charges from the photodiode 101 is interrupted.

Note that while the transfer transistor 102 interrupts the transfer of the charges to the node 107 or the node 107 and the capacitor 108, the charges generated by photoelectric conversion are accumulated in the photodiode 101.

As described above, the node 107 and the capacitor 108 are each capable of accumulating the charges transferred from the photodiode 101 via the transfer transistor 102 and converting the charges into a voltage. Therefore, in the floating state where the reset transistor 103 and/or the switching transistor 104 are/is off, the potential of the node 107 or the potential of the node 107 and the capacitor 108 is modulated in accordance with the amount of charges accumulated therein.

The amplification transistor 105 functions as an amplifier using potential fluctuations of the node 107 connected to the gate of the amplification transistor 105 or potential fluctuations of the node 107 and the capacitor 108 as an input signal and outputs a voltage signal as a pixel signal to the vertical signal line VSL via the selection transistor 106.

The selection transistor 106 enables or disables the output of the voltage signal from the amplification transistor 105 to the vertical signal line VSL in accordance with a selection control signal SEL supplied from the pixel drive circuit 12. For example, when the High-level selection control signal SEL is input to the gate of the selection transistor 106, the voltage signal from the amplification transistor 105 is output to the vertical signal line VSL. On the other hand, when the Low-level selection control signal SEL is input to the gate of the selection transistor 106, the output of the voltage signal from the amplification transistor 105 to the vertical signal line VSL is interrupted. It is therefore possible to extract only the output of the selected unit pixel 131 to the vertical signal line VSL to which the plurality of unit pixels 131 is connected.

As described above, the unit pixel 131 is driven in accordance with the transfer control signal TRG, the reset signal RST, the switching signal FDG, and the selection control signal SEL supplied from the pixel drive circuit 12.

### Increase in Capacitance Per Unit Area

With the configuration of the unit pixel 131 as described above, for example, it is conceivable to adopt a so-called trench capacitor as the capacitor 108 functioning as the second floating diffusion (FD) in order to increase the capacitance per unit area. The trench capacitor herein refers to a vertical capacitor formed in a trench that is formed in a semiconductor substrate.

Here, in a case where the trench capacitor is formed in the same semiconductor substrate as the photodiode 101 is formed, for example, it is conceivable to arrange the photodiode 101 and the trench capacitor in a planar direction. In this case, the area of each unit pixel 131 increases, leading to a decrease in pixel density. On the other hand, to maintain the pixel density, it is necessary to relatively reduce the area of each photodiode 101, but a saturation charge amount Qs decreases accordingly.

Therefore, it is also conceivable that the trench capacitor is formed in a substrate different from the substrate in which the photodiode 101 is formed, and these substrates are bonded to each other. With such a configuration, it is possible to achieve a wide dynamic range by increasing the capacitance per unit area while avoiding problems such as a decrease in pixel density.

However, since a first semiconductor substrate including the photoelectric conversion element and a second semiconductor substrate including the capacitor are separated, two substrates are required, and the process of bonding the substrates together is also required, so that it is difficult to reduce the manufacturing cost.

Therefore, in the present embodiment, in the first semiconductor substrate having a first semiconductor layer and a second semiconductor layer stacked on top of each other, the first semiconductor layer has a photoelectric conversion region and a floating diffusion region, and the second semiconductor layer has a capacitor. Hereinafter, a detailed configuration of the light detection device according to the present embodiment will be described.

### Example of Cross-Sectional Structure of Image Sensor

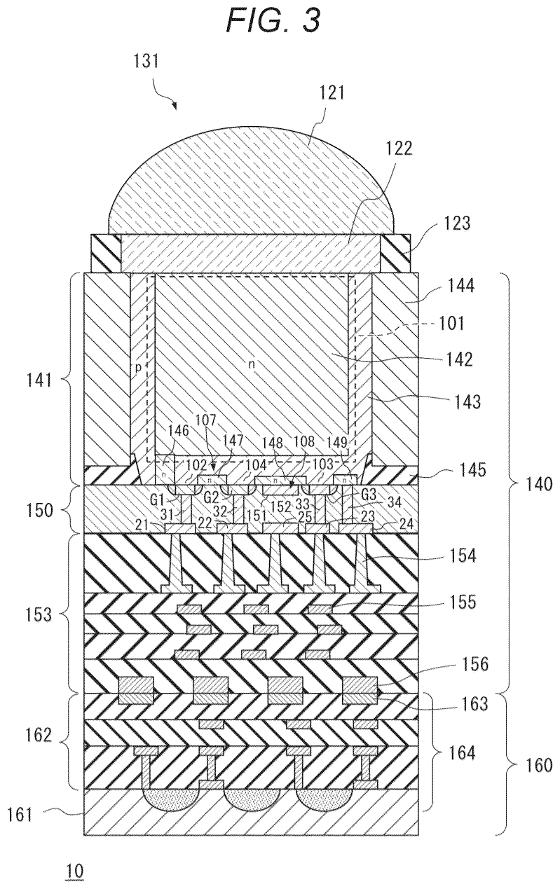

FIG. 3 is a cross-sectional view illustrating an example of a cross-sectional structure of the unit pixel. Note that the drawing illustrates a cross-sectional structure in a normal direction of an incident surface of light with the incident side of the light as being an upper side. In the actual pixel array unit 13, a plurality of unit pixels illustrated in the drawing is arranged on the left and right sides of FIG. 3 and on the front and back sides of the page. The unit pixel in FIG. 3 is of a back-illuminated type, and the upper side of FIG. 3 is the back surface side of the unit pixel.

The image sensor 10 has a multilayer structure including a first semiconductor substrate 140 and a second semiconductor substrate 160 bonded to each other. The first semiconductor substrate 140 includes a first semiconductor layer 141 and a second semiconductor layer 150 stacked on top of each other. The first semiconductor layer 141 and the second semiconductor layer 150 are formed in a substrate, and the second semiconductor layer 150 is a polysilicon layer. Furthermore, the first semiconductor substrate 140 includes an insulator layer 153 on top of which the second semiconductor layer 150 is stacked and that includes a wiring structure.

The transfer transistor 102, the reset transistor 103, the switching transistor 104, the amplification transistor 105, and the selection transistor 106 are formed in the first semiconductor layer 141 and the second semiconductor layer 150. The transistors 102 to 106 have their respective gate electrodes formed in the second semiconductor layer 150. Furthermore, the transistors 102 to 106 have their respective channel regions and source/drain regions formed in the first semiconductor layer 141. Therefore, the transistors 102 to 106 are formed along a boundary between the first semiconductor layer 141 and the second semiconductor layer 150. With such a multilayer structure, the unit pixel 131 is formed in the first semiconductor substrate 140.

### Example of Structure of First Semiconductor Layer

The first semiconductor layer 141 includes the photodiode 101, the node 107, and the channel region and the source/drain region of each transistor. The photodiode 101 receives incident light incident from the back surface (upper surface in the drawing) side of the first semiconductor layer 141. The photodiode 101 is a photoelectric conversion region where the incident light is converted photoelectrically.

A color filter 122 and an on-chip lens 121 are provided above the photodiode 101. Note that a light shielding film 123 may be provided between adjacent color filters 122 in order to prevent light crosstalk between adjacent unit pixels 131. Furthermore, a planarization film (not illustrated) for planarizing a contact surface of the color filter 122 may be provided between the first semiconductor layer 141 and the color filter 122.

In the photodiode 101, for example, an n-type semiconductor region 142 is formed as a charge accumulation region that accumulates charges (electrons). In the photodiode 101, a p-type semiconductor region 143 is provided around the n-type semiconductor region 142.

In the p-type semiconductor region 143, a region on the front surface (lower surface) side of the first semiconductor layer 141 may be higher in impurity concentration than a region on the back surface (upper surface) side, for example. That is, the photodiode 101 may have a hole-accumulation diode (HAD) structure. With such a configuration, it is possible to suppress generation of dark current at each interface on the upper and lower surface sides of the n-type semiconductor region 142.

Near a pixel boundary of the first semiconductor layer 141, a pixel separation section 144 that optically and electrically isolates adjacent photodiodes 101 is provided to prevent crosstalk between the photodiodes 101. In a case where the image sensor 10 is viewed from the upper surface side of the drawing (hereinafter, referred to as “in plan view”), for example, the pixel separation section 144 is formed in a grid pattern to be interposed between adjacent unit pixels 131.

In the pixel separation section 144, an element separation section 145 that is an insulating film is provided at an end opposite to an end where the light shielding film 123 is provided. The element separation section 145 covers the end of the pixel separation section 144. In a manner similar to the pixel separation section 144, the element separation section 145 is formed in a grid pattern to be interposed between adjacent unit pixels 131 in plan view and to electrically isolate the unit pixels 131. Furthermore, the element separation section 145 is wider than the pixel separation section 144. The photodiode 101 is formed in a region defined by the pixel separation section 144 and the element separation section 145. The first semiconductor layer 141 therefore includes a plurality of the pixels 131 each having the photodiode 101, and the pixel boundary region (the pixel separation section 144 and the element separation section 145) arranged between two adjacent pixels 131.

The photodiode 101 has the anode (not illustrated) grounded through a wiring. The n-type semiconductor region 142 serving as the cathode of the photodiode 101 is connected to an n-type semiconductor region 146. The n-type semiconductor region 146 is provided to extend through the p-type semiconductor region 143 to the lower interface of the first semiconductor layer 141. Furthermore, three n-type semiconductor regions 147, 148, and 149 are provided at the lower interface of the first semiconductor layer 141. These n-type semiconductor regions are formed by ion-implantation of n-type impurities at a high concentration into the surface of the p-type semiconductor region 143.

The n-type semiconductor region 146 serves as the source of the transfer transistor 102. The n-type semiconductor region 147 serves as the drain of the transfer transistor 102, the source of the switching transistor 104, and the node 107. With such a configuration, the signal charges (for example, electrons) accumulated in the photodiode 101 are transferred to the node 107 via the transfer transistor 102 connected to the cathode of the photodiode 101.

The node 107 serving as a floating diffusion region accumulates the charges resulting from photoelectric conversion by the photodiode 101. Then, the node 107 applies a voltage corresponding to the amount of the transferred charges to the gate of the amplification transistor 105.

The n-type semiconductor region 148 serves as the drain of the switching transistor 104 and the source of the reset transistor 103. Furthermore, the n-type semiconductor region 148 is connected to a first electrode 151 of the capacitor 108. The n-type semiconductor region 149 serves as the drain of the reset transistor 103.

Note that a p-type semiconductor region that is the channel region of the amplification transistor 105 and the selection transistor 106 and an n-type semiconductor region that is the source/drain region are also provided in a cross section (not illustrated) of the first semiconductor layer 141.

### Example of Structure of Second Semiconductor Layer

As illustrated in FIG. 3, the second semiconductor layer 150 includes respective gate electrodes G1 to G3 of the transistors and the capacitor 108 that accumulates charges resulting from photoelectric conversion by the photodiode 101. Furthermore, the second semiconductor layer 150 is provided with wiring layers 21 to 24 (gate wiring layers) connected to a signal line, a drive line, or the like, and contacts 31 to 34 extending through the second semiconductor layer 150 and connected to the wiring layers 21 to 24, respectively. Note that the respective gate electrodes G1 to G3, wiring layers 21 to 24, and contacts 31 to 34 of the transistors include polysilicon. The first electrode 151 and a second electrode 25 constituting the capacitor 108 also include polysilicon.

The transfer transistor 102 includes the gate electrode G1. The gate electrode G1 is provided between the pair of n-type semiconductor regions 146 and 147 in plan view. The wiring layer 21 is electrically connected to the gate electrode G1 through the contact 31. The gate electrode G1 is formed by forming a gate insulating film (not illustrated) including a silicon oxide film on the first semiconductor layer 141 and then patterning the polysilicon layer. As described above, the transfer transistor 102 includes the gate electrode G1 and the n-type semiconductor regions 146 and 147 as its source/drain regions. The transfer transistor 102 transfers the charges resulting from photoelectric conversion by the photodiode 101 to the n-type semiconductor region 147 that is the node 107.

The switching transistor 104 includes the gate electrode G2. The gate electrode G2 is provided between the pair of n-type semiconductor regions 147 and 148 in plan view. The wiring layer 22 is electrically connected to the gate electrode G2 through the contact 32. The switching transistor 104 includes the gate electrode G2 and the n-type semiconductor regions 147 and 148 as its source/drain regions. With this configuration, the switching transistor 104 switches whether or not to transfer the charges accumulated in the node 107 to the n-type semiconductor region 148 connected to the capacitor 108.

The reset transistor 103 includes the gate electrode G3. The gate electrode G3 is provided between the pair of n-type semiconductor regions 148 and 149 in plan view. The wiring layer 23 is electrically connected to the gate electrode G3 through the contact 33. Furthermore, the wiring layer 24 is electrically connected to the n-type semiconductor region 149 through the contact 34. The reset transistor 103 includes the gate electrode G3 and the n-type semiconductor regions 148 and 149 as its source/drain regions. With this configuration, the reset transistor 103 releases the charges accumulated in the node 107 or the node 107 and the capacitor 108 through the wiring including the contact 34 and the wiring layer 24.

Note that the respective gate electrodes, contacts, and wiring layers of the amplification transistor 105 and the selection transistor 106 are also provided in a cross section (not illustrated) of the second semiconductor layer 150. Therefore, the amplification transistor 105 and the selection transistor 106 are also provided in the first semiconductor substrate 140. All the transistors constituting the pixel 131 are, therefore, formed in the first semiconductor substrate 140.

The capacitor 108 includes the first electrode 151, the second electrode 25, and a dielectric 152. The second electrode 25 is arranged to face the first electrode 151. The dielectric 152 is arranged between the first electrode 151 and the second electrode 25.

The first electrode 151 and the second electrode 25 can be arranged at a layer height that is between the same layer height as the gate electrode G1 of the transfer transistor 102 and the same layer height as the wiring layer 21. In the present embodiment, the first electrode 151 of the capacitor 108 is arranged at the same layer height as the gate electrode G1. This allows the first electrode 151 to be formed simultaneously with the formation of the respective gate electrodes G1 to G3 of the transistors. On the other hand, the second electrode 25 of the capacitor 108 is arranged at the same layer height as the other wiring layers 21 to 24. This allows the second electrode 25 to be formed simultaneously with the formation of the wiring layers 21 to 24. As described above, in the present embodiment, the capacitor 108 can be formed without the need for an additional process. Note that the capacitance of the capacitor 108 may be maintained by setting the first electrode 151 to a predetermined negative potential.

The dielectric 152 includes a silicon oxide film (SiO₂), a Low-k film (low dielectric constant insulating film), or the like. The dielectric 152 according to the present embodiment is an insulating material different from an etching stopper layer (not illustrated) arranged between the wiring layer 21 and the gate electrode G1 and used for formation of each part.

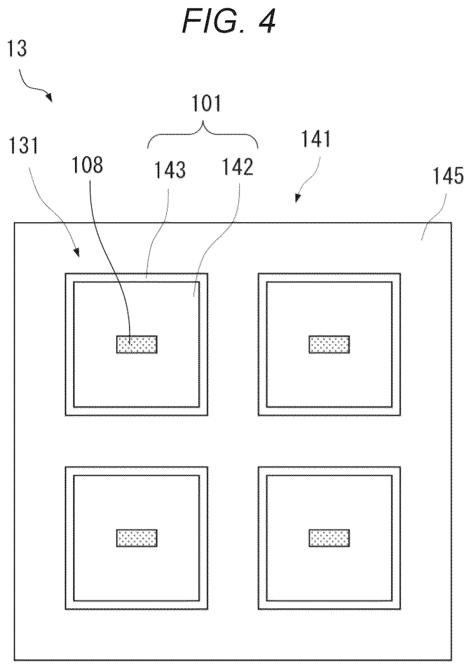

FIG. 4 is a plan view illustrating an arrangement of the capacitors 108 in the pixels 131. The drawing illustrates an area corresponding to a plurality of pixels 131. Note that, for convenience of description, the drawing also illustrates a configuration that does not appear in the same cross section.

As illustrated in the drawing, the element separation section 145 that is the pixel boundary region is arranged between two adjacent pixels 131. The photodiode 101 includes, for example, the n-type semiconductor region 142 formed approximately at the center of a rectangular region assigned to each unit pixel 131 in the first semiconductor layer 141, and the p-type semiconductor region 143 surrounding the n-type semiconductor region 142. Then, the capacitor 108 according to the present embodiment is arranged in a region that does not coincide with the element separation section 145 but coincides with the pixel 131 in plan view. As described above, it is possible to solve, by arranging the capacitor 108 in the region that coincides with the pixel 131, the problems such as a decrease in the pixel density or a decrease in the saturation charge amount Qs with the photodiode 101 prevented from becoming smaller due to the presence of the capacitor 108.

### Example of Structure of Insulator Layer

As illustrated in FIG. 3, the insulator layer 153 is provided on (the lower surface of) the second semiconductor layer 150. The insulator layer 153 includes a via wiring 154, a wiring 155, and an electrode pad 156. The via wiring 154 is provided on the back surface side of the insulator layer 153 to electrically connect to a corresponding one of the wiring layers 21 to 24 each serving as a gate electrode. The via wiring 154 is connected to the corresponding electrode pad 156 through the corresponding wiring 155. The electrode pad 156 includes copper (Cu) on the front surface side (lower surface) of the insulator layer 153, for example.

With such wiring structures, the gate electrode G1 of the transfer transistor 102 is connected to the transfer transistor drive line 112 through the wiring structure including the contact 31, the wiring layer 21, and the via wiring 154. Furthermore, the gate electrode G2 of the switching transistor 104 is connected to the switching transistor drive line 114 through the wiring structure including the contact 32, the wiring layer 22, and the via wiring 154. The gate electrode G3 of the reset transistor 103 is connected to the reset transistor drive line 113 through the wiring structure including the contact 33, the wiring layer 23, and the via wiring 154. The reset transistor 103 has the drain connected to a vertical reset input line (not illustrated) via the wiring structure including the contact 34, the wiring layer 24, and the via wiring 154.

### Example of Structure of Second Semiconductor Substrate

The image sensor 10 includes the second semiconductor substrate 160 arranged on a side opposite to the light incident surface of the first semiconductor substrate 140. The second semiconductor substrate 160 processes a pixel signal corresponding to the charges resulting from photoelectric conversion by the photodiode 101.

A circuit element 164 such as the signal processing circuit 15 in FIG. 1 is provided in the second semiconductor substrate 160. In addition to the signal processing circuit 15, the circuit element 164 may include, for example, the timing control circuit 11, the pixel drive circuit 12, the horizontal transfer circuit 18, the reference voltage generator 17, the output circuit 19, and the like.

The circuit element 164 is formed in a semiconductor substrate 161 and an insulating film 162 provided on (the upper surface of) the semiconductor substrate 161. On the upper surface of the insulating film 162, an electrode pad 163 including copper (Cu) for electrically and mechanically connecting to the electrode pad 156 of the second semiconductor substrate 160 is formed. As described above, the pixel 131 is arranged in the first semiconductor substrate 140, and the second semiconductor substrate 160 in which the peripheral circuits of the pixel 131 are arranged can be directly bonded to the first semiconductor substrate 140 without the use of another member.

### Bonding Between Substrates

With the above configuration, the opposing surfaces of the first semiconductor substrate 140 and the second semiconductor substrate 160 can be bonded to each other by, for example, contact between pads, a via, or a bump. The first semiconductor substrate 140 and the second semiconductor substrate 160 are bonded to each other by so-called Cu-Cu bonding in which the copper (Cu) electrode pads 156 and 163 formed on the respective joint surfaces of the first semiconductor substrate 140 and the second semiconductor substrate 160 are directly bonded to each other. With this configuration, the electrode pads 156 and 163 function as connection portions where the first semiconductor substrate 140 and the second semiconductor substrate 160 are electrically connected and mechanically bonded to each other. Note that the first semiconductor substrate 140 and the second semiconductor substrate 160 may be bonded to each other by so-called direct bonding in which the respective joint surfaces of the first semiconductor substrate 140 and the second semiconductor substrate 160 are planarized and bonded to each other using interelectronic forces.

### Action and Effect

As described above, according to the present embodiment, in the first semiconductor substrate 140 including the first semiconductor layer 141 and the second semiconductor layer 150 stacked on top of each other, the first semiconductor layer 141 includes the photodiode 101 and the node 107. Furthermore, the second semiconductor layer 150 includes the capacitor 108. This configuration allows a reduction in manufacturing cost by reducing the number of required semiconductor substrates and eliminating the need for a bonding process. It is therefore possible to provide a low-cost image sensor 10 with large signal detection capacity.

Furthermore, the first electrode 151 that is a part of the capacitor 108 is arranged at a layer height that is between the same layer height as the gate electrode G1 of the transfer transistor 102 and the same layer height as the wiring layer 21. This allows the capacitor 108 to be formed simultaneously with the formation of the transistors 102 to 106 in the second semiconductor layer 150. Furthermore, in the present embodiment, since the capacitor 108 is arranged on the back surface side of the photodiode 101 and can be formed without affecting the region of the photodiode 101, even if the photodiode 101 and the capacitor 108 are formed in the first semiconductor substrate 140, the saturation charge amount does not decrease.

Moreover, in the present embodiment, it is possible to switch whether or not to use the second floating diffusion (capacitor 108) by controlling the switching transistor 104. With this configuration, it is also possible to switch between a high gain (when the second floating diffusion is not used) and a wide dynamic range (when the second floating diffusion is used) according to a situation such as night shooting.

### SECOND EMBODIMENT

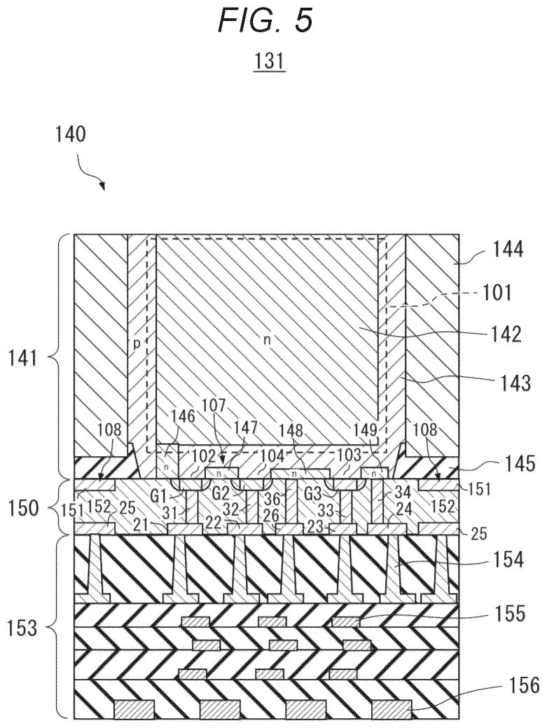

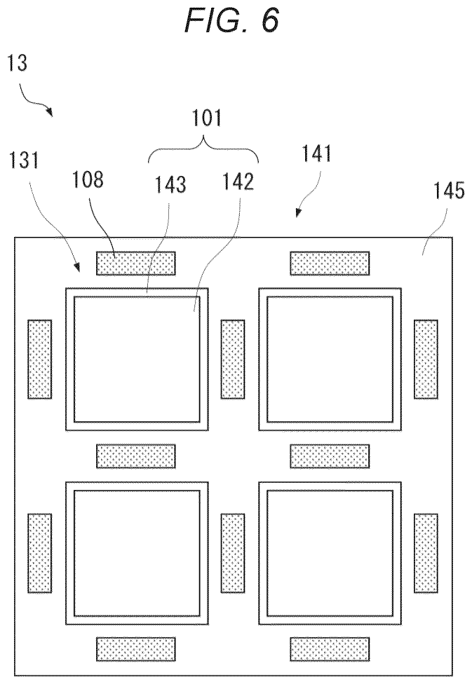

FIG. 5 is an enlarged cross-sectional view illustrating an example of a cross-sectional structure of a unit pixel according to a second embodiment. Note that, in the drawing, for easy understanding, only the first semiconductor substrate 140 that is a part of the pixel 131 is illustrated in an enlarged manner without the illustration of the other components such as the second semiconductor substrate 160. FIG. 6 is a plan view illustrating an arrangement of capacitors in pixels according to the second embodiment. Note that, in each embodiment to be described below, redundant descriptions of the components given in the above-described embodiment will be omitted.

A capacitor 108 of the present embodiment is different from the capacitor 108 of the first embodiment in that the pixel 131 is arranged in a region that coincides with the element separation section 145 serving as the pixel boundary region in plan view.

In the capacitor 108 of the present embodiment, as illustrated in FIG. 5, the first electrode 151, the dielectric 152, and the second electrode 25 are not arranged in a region that coincides with the n-type semiconductor region 148 but are arranged in a region that coincides with the element separation section 145. Therefore, the first electrode 151 is not directly connected to the n-type semiconductor region 148 shared by the source/drain regions of the reset transistor 103 and the switching transistor 104. Therefore, the n-type semiconductor region 148 and the first electrode 151 are electrically connected to each other through a contact 36, a wiring layer 26, and a wiring structure (not illustrated) arranged in a region that coincides with the n-type semiconductor region 148 and electrically connected to the n-type semiconductor region 148. Note that the configuration for electrically connecting such components may be a different configuration.

As described above, it is possible to effectively use the second semiconductor layer 150 by arranging the capacitor 108 in a region that coincides with the element separation section 145. Note that both the capacitor 108 according to the present embodiment and the capacitor 108 according to the first embodiment may be provided in the pixel 131.

Furthermore, as illustrated in FIG. 6, the capacitor 108 according to the present embodiment may be provided between pixels 131 arranged in the matrix direction either individually or in multiple numbers. Furthermore, the capacitor 108 may be arranged between pixels 131 arranged diagonally in the matrix direction. In other words, an additional capacitor 108 may be arranged between adjacent capacitors 108 illustrated in the drawing.

### THIRD EMBODIMENT

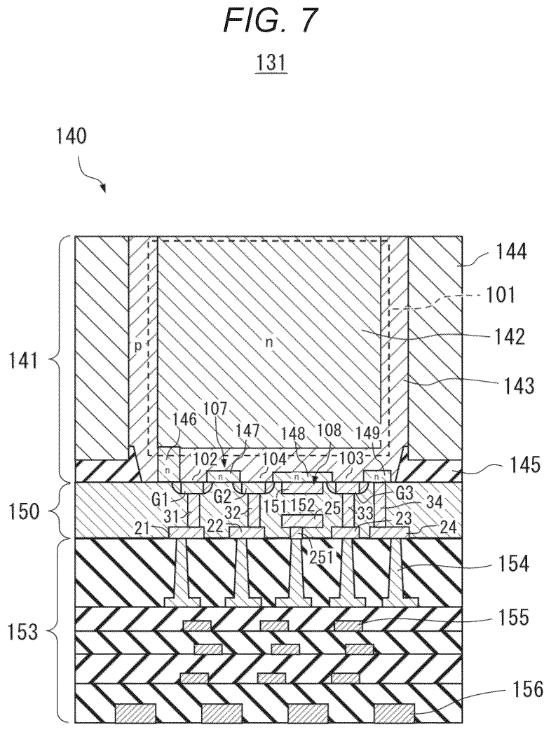

FIG. 7 is an enlarged cross-sectional view illustrating an example of a cross-sectional structure of a unit pixel according to a third embodiment. A capacitor 108 of the present embodiment is different from the capacitor 108 of the first embodiment in the position of the second electrode 25 in a thickness direction of the second semiconductor layer 150 (hereinafter, may be simply referred to as “thickness direction”).

Specifically, the first electrode 151 is arranged at the same layer height as the gate electrodes G1 to G3, but the second electrode 25 is arranged between the gate electrodes G1 to G3 and the wiring layers 21 to 24. That is, the second electrode 25 is arranged in a layer closer to the first electrode 151 and the gate electrodes G1 to G3 than the wiring layers 21 to 24. It is therefore possible to reduce the distance between the electrodes of the capacitor 108 to increase the capacitance of the capacitor 108.

In this case, in order to form the capacitor 108 of the present embodiment, the second electrode 25 is provided as a new layer by a formation process separate from the formation process of the wiring layers 21 to 24. Furthermore, in this formation process, as illustrated in FIG. 7, a wiring layer 251 or a contact (not illustrated) that connects the second electrode 25 to the via wiring 154 is formed.

Note that the capacitor 108 according to the present embodiment may be arranged in a region that coincides with the element separation section 145 as in the second embodiment. Furthermore, the capacitance of the capacitor 108 may be maintained by setting the first electrode 151 to a predetermined negative potential.

### FOURTH EMBODIMENT

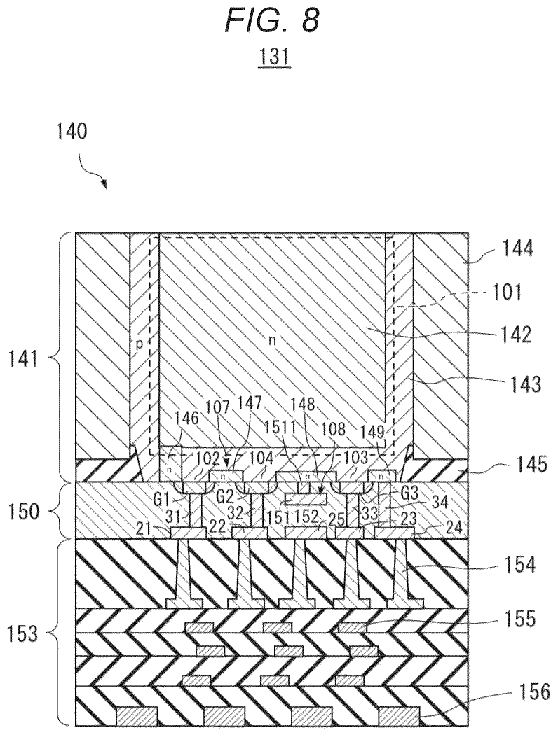

FIG. 8 is an enlarged cross-sectional view illustrating an example of a cross-sectional structure of a unit pixel according to a fourth embodiment. A capacitor 108 of the present embodiment is different from the capacitor 108 of the first embodiment in the position of the first electrode 151 in the thickness direction.

Specifically, the second electrode 25 is arranged at the same layer height as the wiring layer 21 to 24, but the first electrode 151 is arranged between the gate electrodes G1 to G3 and the wiring layers 21 to 24. That is, the first electrode 151 is arranged in a layer closer to the second electrode 25 and the wiring layers 21 to 24 than the gate electrodes G1 to G3. It is therefore possible to reduce the distance between the electrodes of the capacitor 108 to increase the capacitance of the capacitor 108.

In this case, in order to form the capacitor 108 of the present embodiment, the first electrode 151 is provided as a new layer by a formation process separate from the formation process of the gate electrodes G1 to G3. Furthermore, in this formation process, as illustrated in FIG. 8, a contact 1511 that connects the first electrode 151 to the n-type semiconductor region 148 is formed.

Note that the capacitor 108 according to the present embodiment may be arranged in a region that coincides with the element separation section 145 as in the second embodiment. Furthermore, the capacitance of the capacitor 108 may be maintained by setting the first electrode 151 to a predetermined negative potential.

### FIFTH EMBODIMENT

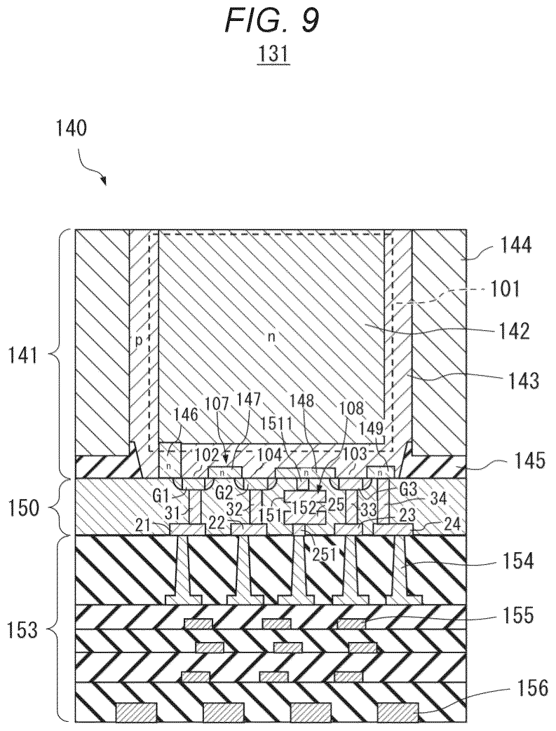

FIG. 9 is an enlarged cross-sectional view illustrating an example of a cross-sectional structure of a unit pixel according to a fifth embodiment. A capacitor 108 of the present embodiment is different from the capacitor 108 of the first embodiment in the positions of the first electrode 151 and the second electrode 25 in the thickness direction.

Both the first electrode 151 and the second electrode 25 of the present embodiment are arranged between the gate electrodes G1 to G3 and the wiring layers 21 to 24. Therefore, the first electrode 151 is arranged between the gate electrodes G1 to G3 and the wiring layers 21 to 24, and the second electrode 25 is arranged between the gate electrodes G1 to G3 and the wiring layers 21 to 24. That is, the first electrode 151 is arranged closer to a second electrode M5 and the wiring layers 21 to 24 than the gate electrodes G1 to G3, and the second electrode 25 is arranged closer to the first electrode 151 and the gate electrodes G1 to G3 than the wiring layers 21 to 24. It is therefore possible to further reduce the distance between the electrodes of the capacitor 108 to further increase the capacitance of the capacitor 108.

In this case, the first electrode 151 is provided as a new layer by a formation process separate from the formation process of the gate electrodes G1 to G3. Furthermore, in this formation process, as illustrated in FIG. 9, a contact 1511 that connects the first electrode 151 to the n-type semiconductor region 148 is formed. Furthermore, in order to form the capacitor 108 of the present embodiment, the second electrode 25 is provided as a new layer by a formation process separate from the formation process of the wiring layers 21 to 24. Furthermore, in this formation process, as illustrated in FIG. 9, a wiring layer 251 or a contact (not illustrated) that connects the second electrode 25 to the via wiring 154 is formed.

Note that the capacitor 108 according to the present embodiment may be arranged in a region that coincides with the element separation section 145 as in the second embodiment. Furthermore, the capacitance of the capacitor 108 may be maintained by setting the first electrode 151 to a predetermined negative potential.

### SIXTH EMBODIMENT

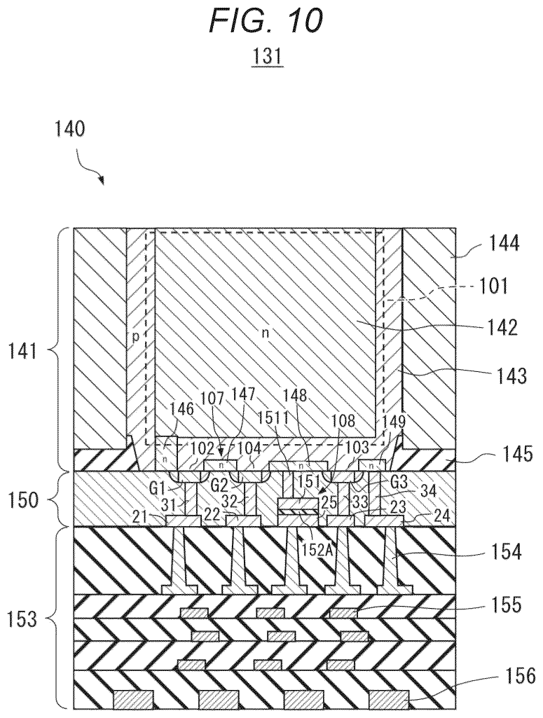

FIG. 10 is an enlarged cross-sectional view illustrating an example of a cross-sectional structure of a unit pixel according to a sixth embodiment. A capacitor 108 of the present embodiment is different from the capacitor 108 of the first embodiment in material of a dielectric 152A arranged between the first electrode 151 and the second electrode 25.

Specifically, the dielectric 152A according to the present embodiment includes the same insulating material as the etching stopper layer arranged between the wiring layer 21 and the gate electrode G1. The etching stopper layer includes, for example, a silicon oxide film and an insulating thin film serving as an etching stopper used in etching for forming a contact opening in the second semiconductor layer 150. As the etching stopper layer, for example, a silicon nitride film (Si₃N₄) is used. Note that the etching stopper layer may include a material other than the silicon nitride film as long as the material has a significant difference in etching rate compared to the silicon oxide film.

As described above, it is possible to use, by using the dielectric 152A as the etching stopper layer used in etching for forming the contact opening, the etching stopper layer temporarily provided for the formation of the second semiconductor layer 150 as it is. It is therefore possible to eliminate the need for a process of removing the etching stopper layer to make the formation process of the second semiconductor layer 150 efficient. Furthermore, as illustrated in the drawing, since the dielectric 152A is an insulating thin film serving as the etching stopper layer, the distance between the first electrode 151 and the second electrode 25 is reduced, which allows an increase in the capacitance of the capacitor 108.

Note that, in order to provide the capacitor 108 with such a configuration, the first electrode 151 is provided as a new layer by a formation process separate from the formation process of the gate electrodes G1 to G3. Furthermore, in this formation process, as illustrated in FIG. 10, a contact 1511 that connects the first electrode 151 to the n-type semiconductor region 148 is formed.

Note that the capacitor 108 according to the present embodiment may be arranged in a region that coincides with the element separation section 145 as in the second embodiment.

Furthermore, the capacitance of the capacitor 108 may be maintained by setting the first electrode 151 to a predetermined negative potential.

### SEVENTH EMBODIMENT

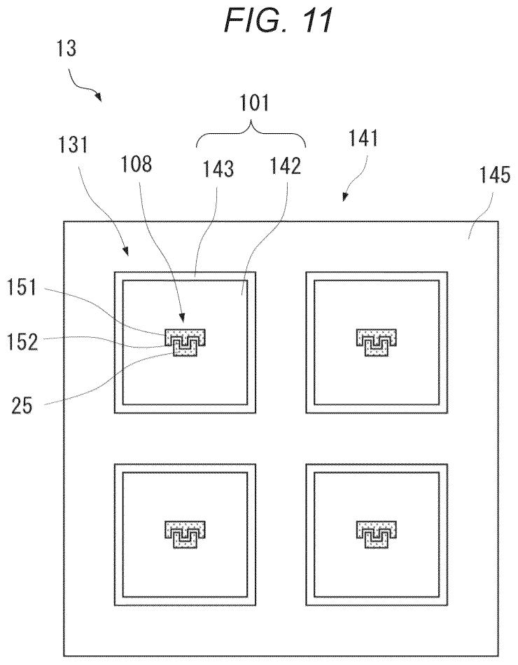

FIG. 11 is a plan view illustrating a shape and arrangement of capacitors in pixels according to a seventh embodiment. A capacitor 108 of the present embodiment is different from the capacitor 108 of the first embodiment in the shapes of the first electrode 151 and the second electrode 25 in plan view. A pixel cross-sectional structure of the seventh embodiment is, for example, similar to that in FIG. 3.

The first electrode 151 and the second electrode 25 of the present embodiment have uneven sections that mesh with each other with a gap between their opposing surfaces in plan view. In other words, the first electrode 151 and the second electrode 25 have comb-shaped portions that mesh with each other. The dielectric 152 is provided between the first electrode 151 and the second electrode 25.

It is therefore possible to increase the capacitance of the capacitor 108 by widening the electrode opposing surfaces of the first electrode 151 and the second electrode 25. Note that the first electrode 151 and the second electrode 25 may be formed to coincide with each other in the thickness direction of the second semiconductor layer 150.

### EIGHTH EMBODIMENT

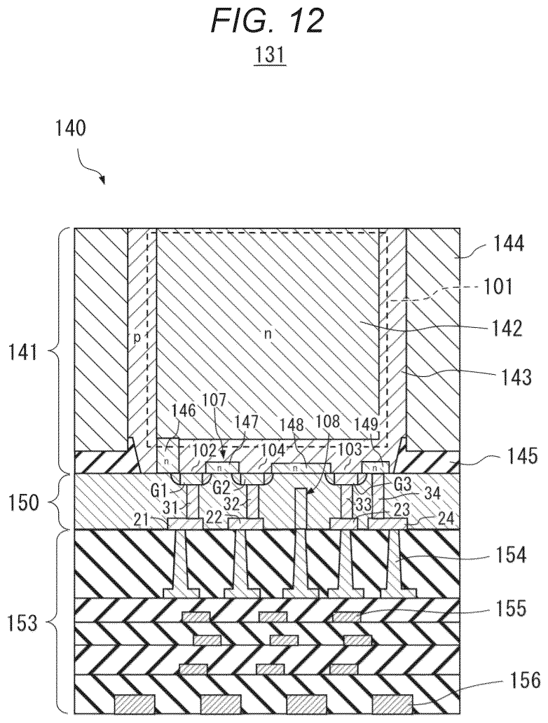

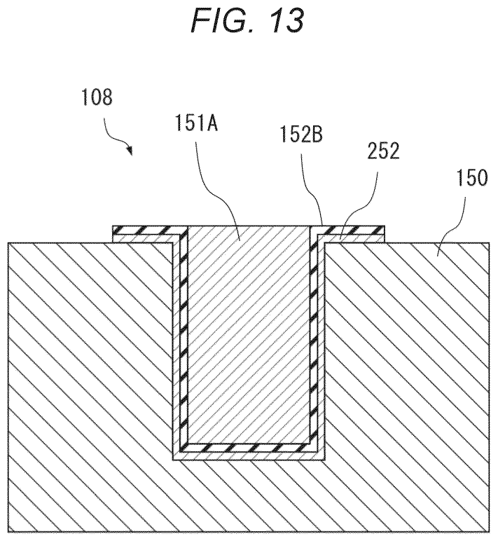

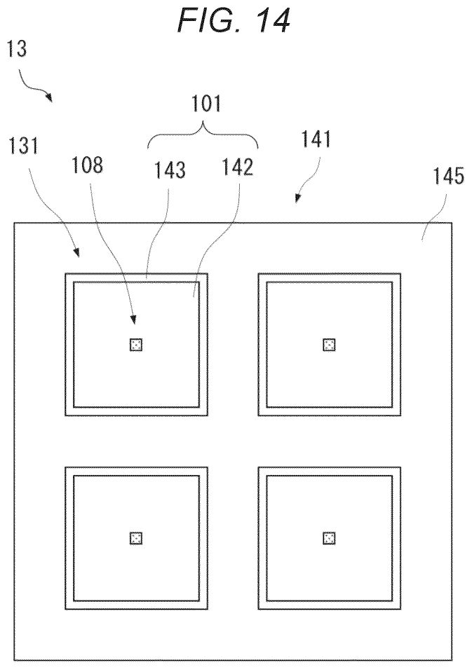

FIG. 12 is an enlarged cross-sectional view illustrating an example of a cross-sectional structure of a unit pixel according to an eighth embodiment. FIG. 13 is an enlarged cross-sectional view illustrating an example of a cross-sectional structure of a capacitor of the eighth embodiment. Note that, for easy understanding, FIG. 13 is illustrated with the orientation reversed from FIG. 12. FIG. 14 is a plan view illustrating an arrangement of capacitors in pixels according to the eighth embodiment.

As illustrated in FIG. 12, the capacitor 108 of the present embodiment is different from the capacitors 108 of the other embodiments in that the capacitor 108 is formed in a plug shape extending from the front surface of the second semiconductor layer 150 toward the back surface. Furthermore, the capacitor 108 of the present embodiment is also different from the capacitors 108 of the above-described embodiments in that the capacitance is formed vertically.

In order to form the capacitor 108 into a plug shape, as illustrated in FIG. 13, one of a first electrode 151A or a second electrode 252 is a columnar member extending in the depth direction of the second semiconductor layer 150. Then, the other electrode is a tubular member that covers at least a side surface of the one electrode with a dielectric 152B interposed therebetween. As an example, the capacitor 108 of the present embodiment includes the first electrode 151A that is a columnar member and the second electrode 252 that is a tubular member covering the first electrode 151A. Furthermore, the capacitor 108 includes the thin dielectric 152B between the first electrode 151A and the second electrode 252.

It is therefore possible to form, by providing the plug-shaped capacitor 108, the capacitor 108 in the vertical direction to make the area in plan view smaller. With this configuration, for example, as illustrated in FIG. 14, when the capacitor 108 is arranged in a region that coincides with the photodiode 101, the region where the capacitor 108 is arranged can be narrowed. It is therefore possible to downsize the pixel 131 or improve performance by adding another transistor, capacitor, or the like.

### NINTH EMBODIMENT

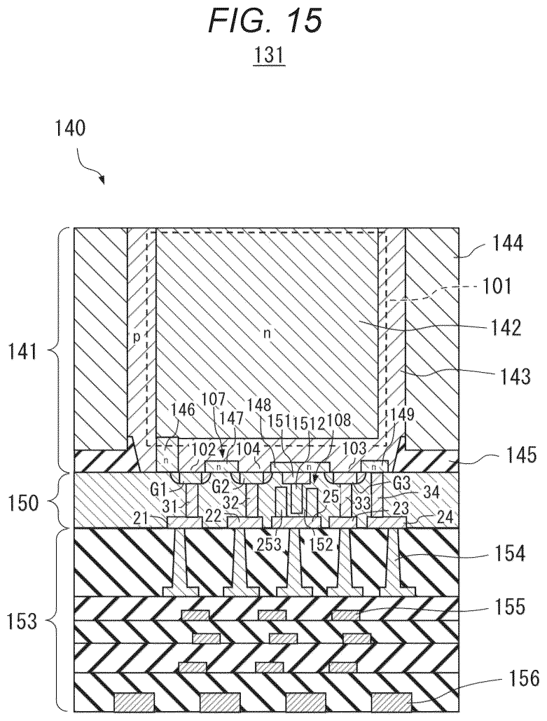

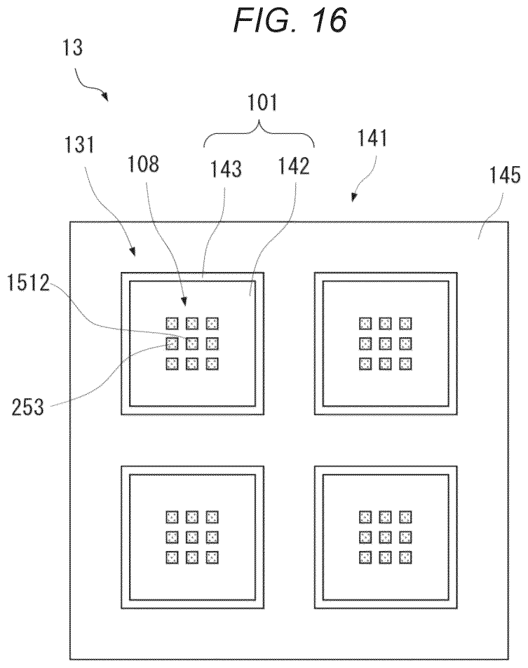

FIG. 15 is an enlarged cross-sectional view illustrating an example of a cross-sectional structure of a unit pixel according to a ninth embodiment. FIG. 16 is a plan view illustrating an arrangement of capacitors in pixels according to the ninth embodiment.

As illustrated in FIG. 15, the capacitor 108 of the present embodiment is different from the capacitors 108 according to the other embodiments in that plug-shaped electrodes extending from each surface of the second semiconductor layer 150 toward the other surface are alternately formed. Note that the capacitor 108 of the present embodiment includes a plurality of plug-shaped electrodes extending in the depth direction and is formed between two adjacent electrodes. In the eighth embodiment, the capacitor 108 is formed in the depth direction, but in the ninth embodiment, the capacitor 108 is formed along the plane direction. Unlike FIG. 13, each plug-shaped electrode includes a conductive material such as polysilicon and does not form a capacitance on its own.

Specifically, in the capacitor 108 of the present embodiment, a plug 1512 extends from the first electrode 151 toward the second electrode 25, and a plug M53 extends from the second electrode 25 toward the first electrode 151. In other words, the first electrode 151 and the second electrode 25 extend in the depth direction of the second semiconductor layer 150. The plug 1512 of the first electrode 151 and 253 of the second electrodes 25 are alternately arranged with a gap. Furthermore, the dielectric 152 is provided between the plug 1512 of the first electrode 151 and 253 of the second electrode 25. With such a configuration, it is possible to increase the capacitance of the capacitor 108 by increasing the area of the electrode to widen the opposing surfaces of the first electrode 151 and the second electrode 25.

### TENTH EMBODIMENT

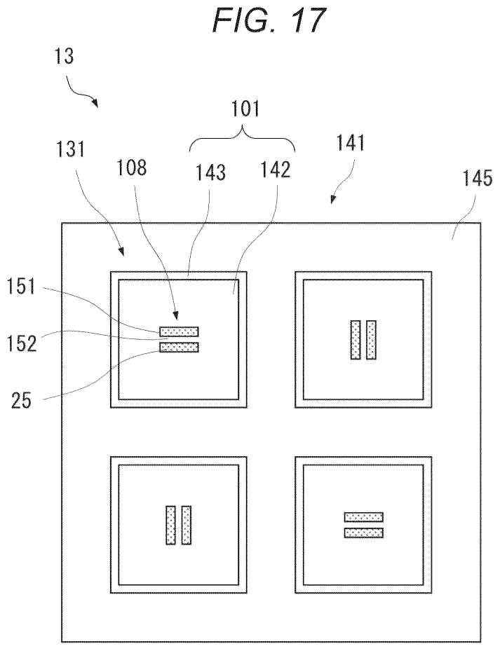

FIG. 17 is a plan view illustrating an arrangement of capacitors in pixels according to a tenth embodiment. As illustrated in FIG. 17, a capacitor 108 of the present embodiment is different from the capacitors 108 according to the other embodiments in that a fin-shaped electrode extending from each surface of the second semiconductor layer 150 toward the other surface is formed. Note that the capacitor 108 of the present embodiment includes a plurality of fin-shaped electrodes extending in the depth direction.

The opposing surfaces of the first electrode 151 and the second electrode 25 are arranged along the depth direction of the second semiconductor layer 150. Furthermore, as illustrated in FIG. 17, two electrodes 151 and M5 included in the capacitor 108 are arranged approximately in parallel in the region of the pixel 131 in plan view. In other words, the electrodes 151 and M5 are provided in approximately parallel lines in plan view. Therefore, the capacitor 108 has a configuration including the dielectric 152 sandwiched between the electrodes 151 and M5.

Furthermore, as illustrated in FIG. 17, in two pixels 131 arranged in the diagonal direction, the directions of the two electrodes 151 and M5 in plan view are the same. Conversely, in two pixels 131 arranged in the horizontal direction or the vertical direction in the matrix direction in which the pixels 131 are arranged, the two electrodes 151 and M5 are provided so that their orientations are tilted by 90 degrees. It is possible to prevent, by changing the direction of the electrodes of the capacitors 108 in two pixels adjacent in the horizontal direction or the vertical direction, coupling between the two capacitors 108 adjacent in the horizontal direction or the vertical direction.

The capacitor 108 is provided as described above to form the capacitance vertically, thereby allowing a reduction in area in plan view. It is therefore possible to downsize the pixel 131 and improve performance by adding another transistor, a capacitor, or the like.

### APPLICATION EXAMPLE

The technology according to the present disclosure can be applied to various products. For example, the technology according to the present disclosure may also be implemented as a device mounted on any kind of moving body such as an automobile, an electric vehicle, a hybrid electric vehicle, a motorcycle, a bicycle, a personal mobility, an airplane, a drone, a vessel, a robot, a construction machine, an agricultural machine (tractor), or the like.

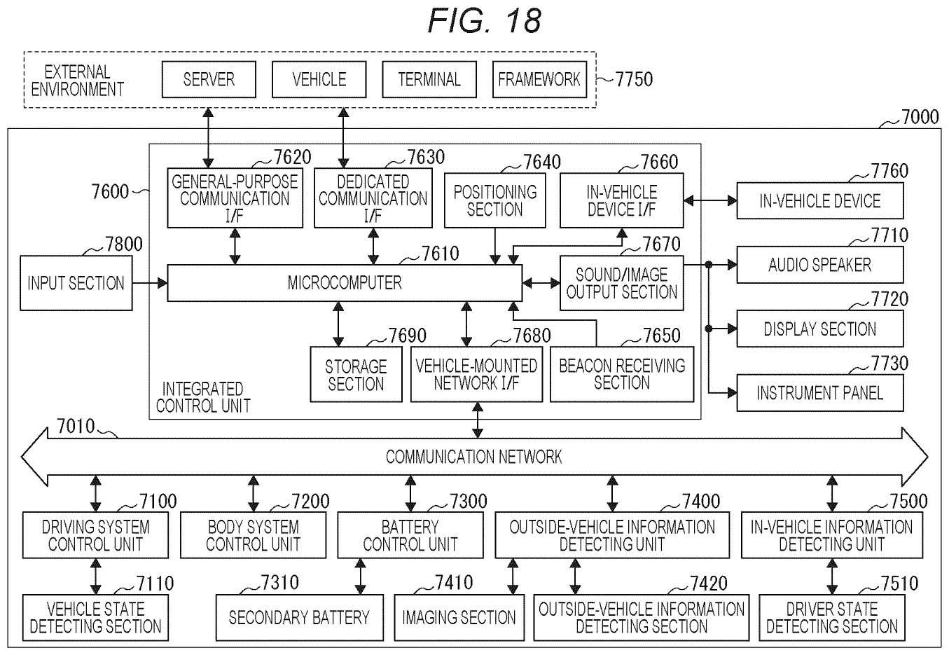

FIG. 18 is a block diagram illustrating an example of a schematic configuration of a vehicle control system 7000 which is an example of a moving body control system to which the technology according to the present disclosure can be applied. The vehicle control system 7000 includes a plurality of electronic control units connected to each other via a communication network 7010. In the example illustrated in FIG. 18, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. In FIG. 18, a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690 are illustrated as functional components of the integrated control unit 7600. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

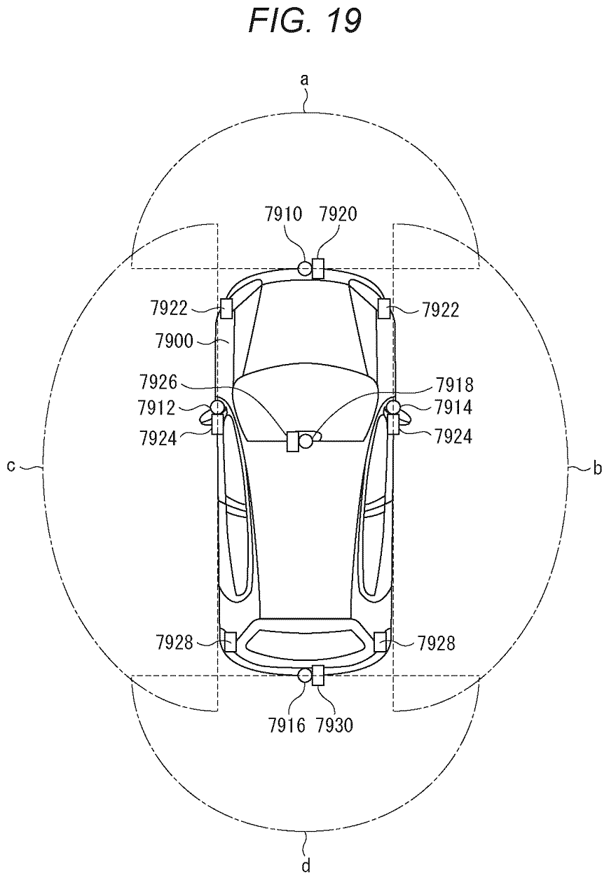

Here, FIG. 19 illustrates an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Note that FIG. 19 illustrates an example of the imaging range of each of the imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Referring back to FIG. 18, the explanation continues. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example in FIG. 18, an audio speaker 7710, a display section 7720, and an instrument panel 7730 are illustrated as output devices. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Note that, in the example illustrated in FIG. 18, at least two control units connected to each other via the communication network 7010 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

Note that the present technology can have the following configurations.
(1) A light detection device including a first semiconductor substrate including a first semiconductor layer and a second semiconductor layer stacked on top of each other, in which
the first semiconductor layer includes a photoelectric conversion region and a floating diffusion region that accumulates charges resulting from photoelectric conversion in the photoelectric conversion region, and
the second semiconductor layer includes a capacitor that accumulates the charges resulting from photoelectric conversion in the photoelectric conversion region.
(2) The light detection device according to (1), in which
the second semiconductor layer includes a gate electrode of a transfer transistor that transfers the charges resulting from photoelectric conversion in the photoelectric conversion region to the floating diffusion region,
the capacitor includes a first electrode, a second electrode arranged to face the first electrode, and a dielectric arranged between the first electrode and the second electrode, and
the first electrode and the second electrode are arranged at a layer height that is between a same layer height as the gate electrode and a same layer height as a wiring layer connected to the gate electrode through a contact.
(3) The light detection device according to (2), in which
the first electrode is arranged at the same layer height as the gate electrode, and
the second electrode is arranged at the same layer height as the wiring layer.
(4) The light detection device according to (2), in which
the first electrode is arranged at the same layer height as the gate electrode, and
the second electrode is arranged between the gate electrode and the wiring layer.
(5) The light detection device according to (2), in which
the first electrode is arranged between the gate electrode and the wiring layer, and
the second electrode is arranged at the same layer height as the wiring layer.
(6) The light detection device according to (2), in which the first electrode and the second electrode are arranged between the wiring layer and the gate electrode.
(7) The light detection device according to any one of (2) to (6), in which the first electrode and the second electrode have uneven sections that mesh with each other with a gap provided between opposing surfaces of the first electrode and the second electrode.
(8) The light detection device according to any one of (2) to (7), in which the dielectric includes an insulating material different from an etching stopper layer arranged between the wiring layer and the gate electrode.
(9) The light detection device according to any one of (2) to (7), in which the dielectric includes a same insulating material as an etching stopper layer arranged between the wiring layer and the gate electrode.
(10) The light detection device according to (2) to (9), in which the gate electrode, the wiring layer, the first electrode, and the second electrode include polysilicon.
(11) The light detection device according to any one of (2) to (10), in which the first electrode is set to a predetermined negative potential.
(12) The light detection device according to (2), in which
one electrode of the first electrode or the second electrode includes a columnar member extending in a depth direction of the second semiconductor layer, and
another electrode of the first electrode or the second electrode includes a tubular member covering at least a side surface of the one electrode with the dielectric interposed therebetween.
(13) The light detection device according to (2), in which the first electrode and the second electrode extend in a depth direction of the second semiconductor layer.
(14) The light detection device according to (2), in which opposing surfaces of the first electrode and the second electrode are arranged along a depth direction of the second semiconductor layer.
(15) The light detection device according to (14), in which the two electrodes of the capacitor are arranged approximately in parallel in a region of a pixel in plan view.
(16) The light detection device according to any one of (1) to (15), in which
the first semiconductor layer includes
a plurality of pixels each having the photoelectric conversion region, and
a pixel boundary region arranged between two pixels adjacent to each other of the plurality of pixels, and
the capacitor is arranged in a region that coincides with each of the pixels in plan view.
(17) The light detection device according to any one of (1) to (11), in which
the first semiconductor layer includes
a plurality of pixels each having the photoelectric conversion region, and
a pixel boundary region arranged between two pixels adjacent to each other of the plurality of pixels, and
the capacitor is arranged in a region that coincides with the pixel boundary region in plan view.
(18) The light detection device according to any one of (1) to (17), in which the second semiconductor layer includes a switching transistor that switches whether or not to transfer the charges accumulated in the floating diffusion region to the capacitor.
(19) The light detection device according to any one of (1) to (18), further including a second semiconductor substrate that is arranged on a side opposite to a light incident surface of the first semiconductor substrate and processes a pixel signal corresponding to the charges resulting from photoelectric conversion in the photoelectric conversion region.
(20) The light detection device according to (19), in which opposing surfaces of the first semiconductor substrate and the second semiconductor substrate are bonded to each other by a contact between pads, a via, or a bump.

Aspects of the present disclosure are not limited to the above-described individual embodiments, but include various modifications that can be conceived by those skilled in the art, and the effects of the present disclosure are not limited to the above-described contents. That is, various additions, modifications, and partial deletions are possible without departing from the conceptual idea and spirit of the present disclosure derived from the matters defined in the claims and equivalents thereof.

### REFERENCE SIGNS LIST

10 Image sensor
11 Timing control circuit
12 Pixel drive circuit
13 Pixel array unit
15 Signal processing circuit
15a AD conversion circuit
17 Reference voltage generator
18 Horizontal transfer circuit
19 Output circuit
21 to 24, 26 Wiring layer
25 Second electrode
31 to 34, 36 Contact
101 Photodiode
102 Transfer transistor
103 Reset transistor
104 Switching transistor
105 Amplification transistor
106 Selection transistor
107 Node
108 Capacitor
112 Transfer transistor drive line
113 Reset transistor drive line
114 Switching transistor drive line
117 Selection transistor drive line
121 On-chip lens
122 Color filter
123 Light shielding film
131 Pixel
140 First semiconductor substrate
141 First semiconductor layer
142, 146, 147, 148, 149 n-type semiconductor region
143 p-type semiconductor region
144 Pixel separation section
145 Element separation section
150 Second semiconductor layer
151, 151A First electrode
152, 152A, 152B Dielectric
153 Insulator layer
154 Via wiring
155 Wiring
156, 163 Electrode pad
160 Second semiconductor substrate
161 Semiconductor substrate
162 Insulating film
164 Circuit element
G1 to G3 Gate electrode

What is claimed is:

1. A light detection device comprising a first semiconductor substrate including a first semiconductor layer and a second semiconductor layer stacked on top of each other, wherein
the first semiconductor layer includes a photoelectric conversion region and a floating diffusion region that accumulates charges resulting from photoelectric conversion in the photoelectric conversion region, and
the second semiconductor layer includes a capacitor that accumulates the charges resulting from photoelectric conversion in the photoelectric conversion region.

2. The light detection device according to claim 1, wherein
the second semiconductor layer includes a gate electrode of a transfer transistor that transfers the charges resulting from photoelectric conversion in the photoelectric conversion region to the floating diffusion region,
the capacitor includes a first electrode, a second electrode arranged to face the first electrode, and a dielectric arranged between the first electrode and the second electrode, and
the first electrode and the second electrode are arranged at a layer height that is between a same layer height as the gate electrode and a same layer height as a wiring layer connected to the gate electrode through a contact.

3. The light detection device according to claim 2, wherein
the first electrode is arranged at the same layer height as the gate electrode, and
the second electrode is arranged at the same layer height as the wiring layer.

4. The light detection device according to claim 2, wherein
the first electrode is arranged at the same layer height as the gate electrode, and
the second electrode is arranged between the gate electrode and the wiring layer.

5. The light detection device according to claim 2, wherein
the first electrode is arranged between the gate electrode and the wiring layer, and
the second electrode is arranged at the same layer height as the wiring layer.

6. The light detection device according to claim 2, wherein the first electrode and the second electrode are arranged between the wiring layer and the gate electrode.

7. The light detection device according to claim 2, wherein the first electrode and the second electrode have uneven sections that mesh with each other with a gap provided between opposing surfaces of the first electrode and the second electrode.

8. The light detection device according to claim 2, wherein the dielectric includes an insulating material different from an etching stopper layer arranged between the wiring layer and the gate electrode.

9. The light detection device according to claim 2, wherein the dielectric includes a same insulating material as an etching stopper layer arranged between the wiring layer and the gate electrode.

10. The light detection device according to claim 2, wherein the gate electrode, the wiring layer, the first electrode, and the second electrode include polysilicon.

11. The light detection device according to claim 2, wherein the first electrode is set to a predetermined negative potential.

12. The light detection device according to claim 2, wherein
one electrode of the first electrode or the second electrode includes a columnar member extending in a depth direction of the second semiconductor layer, and
another electrode of the first electrode or the second electrode includes a tubular member covering at least a side surface of the one electrode with the dielectric interposed therebetween.

13. The light detection device according to claim 2, wherein the first electrode and the second electrode extend in a depth direction of the second semiconductor layer.

14. The light detection device according to claim 2, wherein opposing surfaces of the first electrode and the second electrode are arranged along a depth direction of the second semiconductor layer.

15. The light detection device according to claim 14, wherein the two electrodes of the capacitor are arranged approximately in parallel in a region of a pixel in plan view.

16. The light detection device according to claim 1, wherein
the first semiconductor layer includes
a plurality of pixels each having the photoelectric conversion region, and
a pixel boundary region arranged between two pixels adjacent to each other of the plurality of pixels, and
the capacitor is arranged in a region that coincides with each of the pixels in plan view.

17. The light detection device according to claim 1, wherein
the first semiconductor layer includes
a plurality of pixels each having the photoelectric conversion region, and
a pixel boundary region arranged between two pixels adjacent to each other of the plurality of pixels, and
the capacitor is arranged in a region that coincides with the pixel boundary region in plan view.

18. The light detection device according to claim 1, wherein the second semiconductor layer includes a switching transistor that switches whether or not to transfer the charges accumulated in the floating diffusion region to the capacitor

19. The light detection device according to claim 1, further comprising a second semiconductor substrate that is arranged on a side opposite to a light incident surface of the first semiconductor substrate and processes a pixel signal corresponding to the charges resulting from photoelectric conversion in the photoelectric conversion region.

20. The light detection device according to claim 19, wherein opposing surfaces of the first semiconductor substrate and the second semiconductor substrate are bonded to each other by a contact between pads, a via, or a bump.
